(19) United States
(12) Patent Application Publication
(10) Pub. No.: US 2012/0017985 A1
(43) Pub. Date: Jan. 26, 2012

(54) Solar Cells With An Encapsulating Layer Based On Polysilazane

(75) Inventors: Klaus Rode, Wiesbaden (DE); Sandra Stojanovic, Gersthofen (DE); Jan Schniebs, Berlin (DE); Christian Kaufmann, Berlin (DE); Hans-Werner Schock, Stuttgart (DE)

(73) Assignee: CLARIANT FINANCE (BVI) LIMITED, Tortola (VG)

(21) Appl. No.: 13/257,044

(22) PCT Filed: Mar. 16, 2010
(86) PCT No.: PCT/EP2010/001636

§ 371 Date: Sep. 16, 2011

(30) Foreign Application Priority Data
Mar. 19, 2009 (DE) 10 2009 013 904.4

(51) Int. Cl. H01L 31/0203; H01L 31/18; H01L 31/0224

(52) U.S. Cl. 136/256; 136/259; 438/95; 257/E31.027

(57) ABSTRACT

The invention relates to a thin-film solar cell (10) comprising a substrate (1) of metal or glass, a photovoltaic layer structure (4) of the copper-indium sulphide (CIS) type or the copper-indium-gallium selenide (CIGSe) type, and an encapsulating layer (5) based on a polysilazane.

The present invention relates to a chalcopyrite solar cell comprising a substrate and a photovoltaic layer structure. More particularly, it is a thin-film solar cell with a photovoltaic layer structure of the copper indium sulfide (CIS) or copper indium gallium selenide (CIGSe) type.

The invention further relates to a process for producing solar cells based on chalcopyrite. In the course of the process, the solar cell is provided with an encapsulation layer, which is obtained by hardening a solution of polysilazanes and additives at a temperature in the range from 20 to 1000° C., especially 80 to 200° C.

In view of the scarcity of fossil resources, photovoltaics are gaining great significance as a renewable and environmentally sound energy source. Solar cells convert sunlight to electric current. Crystalline or amorphous silicon is the predominant light-absorbing semiconductive material used in solar cells. The use of silicon is associated with considerable costs. In comparison, thin-film solar cells with an absorber composed of a chalcopyrite material, such as copper indium sulfide (CIS) or copper indium gallium selenide (CIGSe), can be produced with significantly lower costs.

It is a very general requirement for rapid widening of photovoltaic use to improve the cost-benefit ratio of photovoltaic energy generation. For this purpose, it is desirable to increase the efficiency and the lifetime of solar cells. The efficiency of a solar cell is defined as the ratio of electrical power, i.e. the product of voltage and photocurrent, to incident light power. Efficiency is proportional inter alia to the number of photons which penetrate into the absorber layer and can contribute to the generation of electron-hole pairs. Photons which are reflected at the surface of the solar cell make no contribution to the photocurrent. Accordingly, the efficiency can be increased by a reduction in the light reflection at the surface of the solar cell. The lifetime of solar cells can be prolonged by improved protection against weathering-related degradation processes. Penetrating water or water vapor accelerates the degradation processes. To shield solar cells from water vapor, an encapsulation composed of a layer composite comprising glass and EVA and optionally PVA and other polymer films is therefore used in the prior art.

However, the materials used for encapsulation in the prior art have disadvantages. Glass in particular leads to high module weights, which places increased demands, for example, on the structure of roofs, and PVA and PVB, under the action of light, together with traces of water, release acids which impair the function of the solar cells. The efficacy of front diffusion barriers or encapsulation layers is tested with the aid of accelerated aging tests to DIN EN 61646 in climate-controlled chambers. Encapsulated solar modules are stored at 85° C. and 85% relative air humidity for longer than 1000 h, and analyzed for their electrical characteristics at regular intervals, and the degradation is thus determined.

The use of SiOₓ layers for front encapsulation of solar cells is known. Such SiOₓ layers are deposited from the gas phase by means of CVD processes such as microwave plasma-supported gas phase deposition (MWPECVD) and PVD processes such as magnetron sputtering. These vacuum processes are associated with high costs and additionally have the disadvantage that the layers produced thereby have low adhesion and mechanical strength. CVD processes also require the use of inflammable (SiH₄, CH₄, H₂) and toxic (NH₃) gases.

The substrate materials used for chalcopyrite solar cells are glass or foils of metal or polyimide. Glass is found to be advantageous in many ways, since it is electrically insulating, has a smooth surface and provides sodium during the production of the chalcopyrite absorber layer, which diffuses out of the glass into the absorber layer and, as a dopant, improves the properties of the absorber layer. Disadvantages of glass are its high weight and inadequate flexibility. In particular, glass substrates, owing to their stiffness, cannot be coated in inexpensive roll-to-roll processes. Foil-type substrates composed of metal or plastic are lighter than glass and flexible, such that they are suitable for the production of solar cells by means of an inexpensive roll-to-roll process. However, metal or polymer foils, according to their properties, can adversely affect the property of the chalcopyrite layer composite, and additionally do not possess a sodium depot for absorber doping. Owing to the elevated temperatures (in some cases above 500° C.) to which the substrate is exposed during the production of the solar cells, preference is given to using metal foils of steel or titanium.

For the purpose of monolithic interconnection of solar cells on titanium or steel foil, the photovoltaic layer structure or the rear contact must be electrically insulated from the substrate foil. For this purpose, a layer of an electrically insulating material is applied to the metallic substrate foil. This electrically insulating layer should additionally act as a diffusion barrier in order to prevent the diffusion of metal ions, which can damage the absorber layer. For example, iron atoms can increase the recombination rate of charge carriers (electrons and holes) in chalcopyrite absorber layers, which decreases the photocurrent. A suitable material for insulating and diffusion-inhibiting barrier layers is silicon oxide (SiOₓ).

The prior art discloses use of protective or encapsulation layers which consist essentially of SiOₓ or SiNₓ for electronic components and solar cells based on silicon or other semiconductor materials.

U.S. Pat. No. 7,067,069 discloses an insulating encapsulation layer of SiO₂ for silicon-based solar cells, wherein the SiO₂ layer is obtained by applying polysilanes and then hardening at a temperature of 100 to 800° C., preferably of 300 to 500° C.

U.S. Pat. No. 6,501,014 B1 relates to articles, especially solar cells based on amorphous silicon, having a transparent, heat- and weathering-resistant protective layer of a silicate-like material. The protective layer is obtained in a simple manner using a polysilazane solution. Between the protective layer based on polysilazane and the photovoltaic layer system is arranged a flexible rubberlike adhesive or buffer layer.

U.S. Pat. No. 7,396,563 teaches the deposition of dielectric and passivating polysilazane layers by means of PA-CVD, wherein polysilanes are used as the CVD precursor.

U.S. Pat. No. 4,751,191 discloses the deposition of polysilazane layers for solar cells by means of PA-CVD. The resulting polysilazane layer is structured photolithographically, and serves for masking of metallic contacts and as an antireflection layer.

The solar cells with encapsulation layers composed of SiOₓ or SiNₓ, described in the prior art, are costly and inconvenient to produce and require the use of two- or multi-ply composite layers which, as well as the encapsulation layer, comprise a carrier film, a buffer layer, an adhesion promoter layer and/or a reflector layer. Especially for solar cells whose photovoltaic absorbers are not based on silicon, buffer layers which compensate for the thermal mismatch to the encapsulation layer are required. Thermal mismatch, i.e. differences in the thermal expansion coefficients of adjacent layers, causes mechanical stresses which frequently lead to cracking and detachment. One way of counteracting this problem is to deposit the encapsulation layer on the solar cell at low temperatures. However, such encapsulation layers obtained at low temperature usually have insufficient barrier action against water vapor and oxygen.

In view of the prior art, the present invention has for its object to provide a chalcopyrite solar cell with high efficiency and high stability to aging, and also an inexpensive process for production thereof.

This object is achieved by a chalcopyrite solar cell comprising a substrate, a photovoltaic layer structure and an encapsulation layer based on polysilazane.

The invention is illustrated hereinafter with reference to figures, which show:

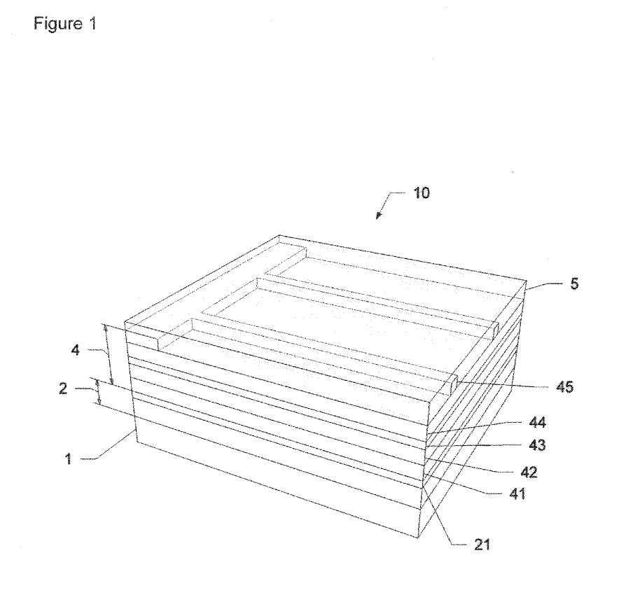

FIG. 1 a perspective section of a solar cell, and

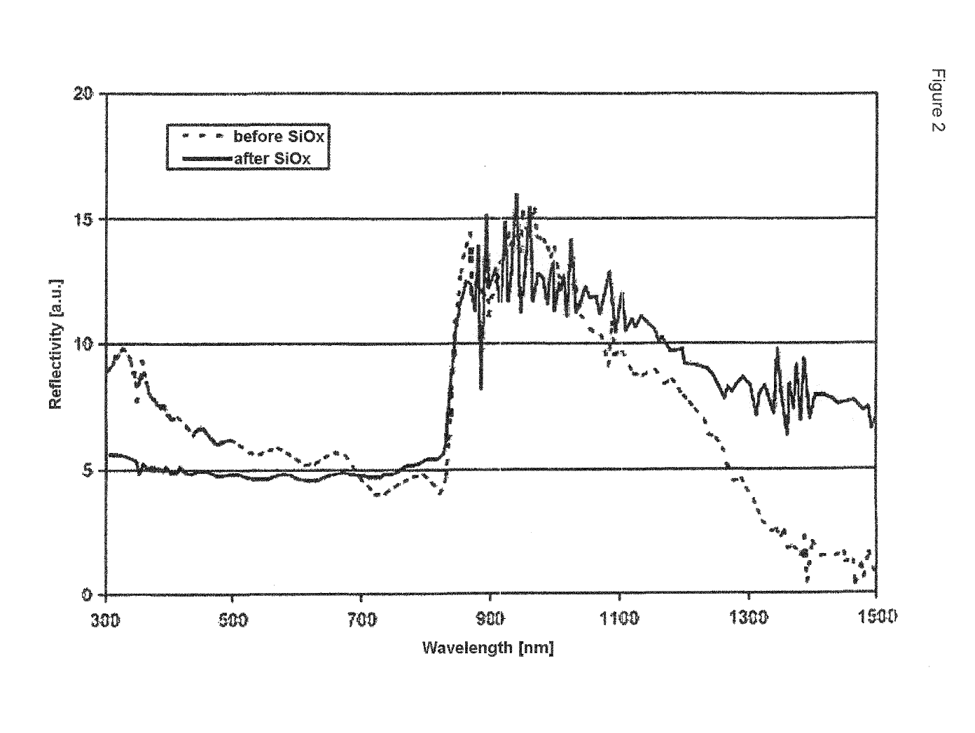

FIG. 2 reflection curves of a solar cell without and with encapsulation layer.

FIG. 1 shows a perspective view of a section through an inventive solar cell 10 comprising a substrate 1, an optional barrier layer 2, a photovoltaic layer structure 4 and an encapsulation layer 5. The solar cell 10 is preferably configured as a thin-film solar cell and has a photovoltaic layer structure 4 of the copper indium sulfide (CIS) or copper indium gallium selenide (CIGSe) type.

The inventive encapsulation layer 5 has a first and second surface which are opposite one another. In a preferred embodiment, the first surface of the encapsulation layer directly adjoins the photovoltaic layer structure 4, and the second surface of the encapsulation layer forms the outside of the solar cell.

Characteristic features of the inventive solar cell 10 are that:
it is configured as a thin-film solar cell and has a photovoltaic layer structure 4 of the copper indium sulfide (CIS) or copper indium gallium selenide (CIGSe) type;
the photovoltaic layer structure 4 comprises a rear contact 41 composed of molybdenum, an absorber 42 of the composition CuInSe₂, CuInS₂, CuGaSe₂, CuIn₁₋ₓGaₓSe₂ where 0<x≦0.5 or Cu(InGa)(Se_{1-y}S_{y})₂ where 0<y≦1, a buffer 43 composed of CdS, a window layer 44 composed of ZnO or ZnO:Al, and a front contact 45 composed of Al or silver;
the substrate 1 consists of a material comprising metal, metal alloys, glass, ceramic or plastic;
the substrate 1 is in the form of a foil, especially in the form of a steel or titanium foil;
the encapsulation layer 5 has a thickness of 100 to 3000 nm, preferably of 200 to 2500 nm, and especially of 300 to 2000 nm;
the substrate 1 consists of an electrically conductive material, and one or more of the layers of which the photovoltaic layer structure 4 is composed has/have been deposited electrolytically;
the solar cell 1 comprises a barrier layer 2 based on polysilazane arranged between the substrate 1 and the photovoltaic layer structure 4;
the barrier layer 2 contains sodium or comprises a sodium-containing precursor layer 21;
the encapsulation layer 5 and optionally the barrier layer 2 consist(s) of a hardened solution of polysilazanes and additives in a solvent which is preferably dibutyl ether;
the polysilazanes have the general structural formula (I)

—(SiR′R″—NR′″)n- (I)
where R′, R″, R′″ are the same or different and are each independently hydrogen or an optionally substituted alkyl, aryl, vinyl or (trialkoxysilyl)alkyl radical, where n is an integer and is such that the polysilazane has a number-average molecular weight of 150 to 150 000 g/mol, preferably of 50 000 to 150 000 g/mol, and especially of 100 000 to 150 000 g/mol;
at least one polysilazane is selected from the group of the perhydropolysilazanes where R′, R″ and R′″═H;
the solar cell has a mean relative reflectivity for light in the wavelength range from 300 to 900 nm of less than 97%, preferably of less than 96% and especially of less than 95%, based on the reflectivity of the solar cell 10 before application of the encapsulation layer 5;

and
the solar cell 10 has a mean relative reflectivity for light in the wavelength range from 1100 to 1500 nm of more than 120%, preferably of more than 150% and especially of more than 200%, based on the reflectivity of the solar cell 10 before application of the encapsulation layer 5.

FIG. 2 shows the results of a measurement of the spectral reflectivities of a chalcopyrite solar cell with and without an inventive encapsulation layer based on polysilazane (designated in FIG. 2 by a continuous line “with SiOₓ” and a broken line “without SiOₓ”). The spectral reflectivities are measured based on DIN EN ISO 8980-4 on inventive solar cells with an encapsulation layer and on reference solar cells without an encapsulation layer. The inventive and reference solar cells have the same structure—apart from the encapsulation layer—and have passed through the same production process. To determine the mean relative reflectivity, the resultant spectral reflection curves are superimposed and evaluated numerically in two wavelength ranges of 300 to 900 nm and of 1100 to 1500 nm. In each of the abovementioned wavelength ranges, the quotient of the reflection values of the inventive solar cell and of the reference solar cell is calculated at equidistant sampling points, the distance of which from one another may be selected within the range from 1 to 20 nm, and the mean of the quotients of all sampling points within the range is formed.

Within the wavelength range from 300 to 900 nm, the inventive solar cells have a mean relative reflectivity of less than 97% down to less than 95%. The reflectivity is a factor in the external quantum efficiency (EQE) and the efficiency of a solar cell. Accordingly, the inventive encapsulation layer increases the external quantum efficiency of a solar cell by an average of more than 3% to more than 5% compared to a reference solar cell. The encapsulation layers known from the prior art raise the mean reflectivity by a maximum of 2% relative to the reference. It is thus possible by means of the inventive encapsulation layer to increase the efficiency of a conventional chalcopyrite solar cell by a factor of 1.01 to 1.03.

Given an efficiency of, for example, 15%, this corresponds to an improvement by more than 0.15% to 0.45%.

The efficiency of chalcopyrite solar cells declines with rising temperature. Owing to increased reflectivity for infrared light, the inventive encapsulation layer reduces the heating of the solar cell caused by solar irradiation, and thus contributes in this way too to an increase in the efficiency. Within the wavelength range from 1100 to 1500 nm, the inventive solar cell has a mean relative reflectivity of greater than 120% up to more than 200%.

In an accelerated aging test to DIN EN 61646 (damp heat test at a temperature of 85° C. and 85% relative air humidity), the inventive solar cells after 800 h exhibit an efficiency of greater than 70%, preferably greater than 75% and especially greater than 80%, based on the starting value, i.e. before commencement of the aging test.

The process for producing the inventive solar cells comprises the following steps a) to f):
a) applying a photovoltaic layer structure based on chalcopyrite to a substrate optionally provided with a barrier layer,
b) coating the photovoltaic layer structure with a solution comprising at least one polysilazane of the general formula (I)

—(SiR′R″—NR′″)n- (I)
where R′, R″, R′″ are the same or different and are each independently hydrogen or an optionally substituted alkyl, aryl, vinyl or (trialkoxysilyl)alkyl radical, where n is an integer and is such that the polysilazane has a number-average molecular weight of 150 to 150 000 g/mol, preferably of 50 000 to 150 000 g/mol, and especially of 100 000 to 150 000 g/mol,
c) removing the solvent by evaporation to obtain a polysilazane layer having a thickness of 100 to 3000 nm, preferably of 200 to 2500 nm, and especially of 300 to 2000 nm,
d) optionally repeating steps b) and c) once or more than once,
e) hardening the polysilazane layer by i) heating to a temperature in the range from 20 to 1000° C., especially 80 to 200° C., and/or ii) irradiating with UV light having wavelength components in the range from 180 to 230 nm, the heating and/or irradiation being effected over a period of 1 min to 14 h, preferably 1 min to 60 min and especially 1 min to 30 min, preferably in an atmosphere of water vapor-containing air or nitrogen,

and
f) optionally further hardening the polysilazane layer at a temperature of 20 to 1000° C., preferably 60 to 130° C., in air having a relative humidity of 60 to 90% over a period of 1 min to 2 h, preferably 30 min to 1 h.

In advantageous configurations of the process according to the invention, the polysilazane solution used for coating comprises one or more of the following constituents:
at least one perhydropolysilazane where R′, R″ and R′″═H; and
a catalyst, and optionally further additives.

The chalcopyrite solar cells are preferably manufactured on a flexible weblike substrate in a roll-to-roll process.

In the polysilazane solution used to produce the inventive encapsulation layer, the proportion of polysilazane is 1 to 80% by weight, preferably 2 to 50% by weight and especially 5 to 20% by weight, based on the total weight of the solution.

Suitable solvents are especially organic, preferably aprotic solvents which do not contain any water or any reactive groups such as hydroxyl or amino groups, and are inert toward the polysilazane. Examples are aromatic or aliphatic hydrocarbons and mixtures thereof. Examples include aliphatic or aromatic hydrocarbons, halohydrocarbons, esters such as ethyl acetate or butyl acetate, ketones such as acetone or methyl ethyl ketone, ethers such as tetrahydrofuran or dibutyl ether, and also mono- and polyalkylene glycol dialkyl ethers (Glymes) or mixtures of these solvents.

Additional constituents of the polysilazane solution may be catalysts, for example organic amines, acids, and metals or metal salts or mixtures of these compounds which accelerate the layer formation process. Suitable amine catalysts are especially N,N-diethylethanolamine, N,N-dimethylethanolamine, N,N-dimethylpropanolamine, triethylamine, triethanolamine and 3-morpholinopropylamine. The catalysts are used preferably in amounts of 0.001 to 10% by weight, especially 0.01 to 6% by weight, more preferably 0.1 to 5% by weight, based on the weight of the polysilazane.

A further constituent may be additives for substrate wetting and film formation, and also inorganic nanoparticles of oxides such as SiO₂, TiO₂, ZnO, ZrO₂ or Al₂O₃.

To produce the inventive solar cell, a photovoltaic layer structure based on chalcopyrite is obtained by known processes on a substrate such as a steel foil. Before the application of the photovoltaic layer structure, the steel foil is preferably provided with an electrically insulating layer, especially with an SiOₓ barrier layer based on polysilazane. As a rear contact, a molybdenum layer of thickness about 1 μm is deposited thereon by means of DC magnetron sputtering, and preferably structured for a monolithic interconnection (P1 section). The division of the molybdenum layer into strips which is required for this purpose is undertaken with a laser cutting device.

The chalcopyrite absorber layer is prepared preferably in a 3-stage PVD process at a pressure of about 3·10⁻⁶ mbar. The total duration of the PVD process is about 1.5 h. It is advantageous here to conduct the processes such that the substrate assumes a maximum temperature below 400° C.

The final deposition of the CdS buffer layer is effected by wet-chemical means at a temperature of about 60° C. The window layer composed of i-ZnO and aluminum-doped ZnO is deposited by means of DC magnetron sputtering.

To produce the inventive encapsulation layer, a polysilazane solution of the above-described composition is applied by conventional coating processes, for example by means of spray nozzles or a dipping bath, to a substrate, preferably to a steel foil, and optionally smoothed with an elastic coating bar, in order to ensure a homogeneous thickness distribution or material coverage on the photovoltaic layer structure. In the case of flexible substrates such as foils of metal or plastic which are suitable for roll-to-roll coating, it is also possible to use slot dies as an application system for the attainment of very thin homogeneous layers. Thereafter, the solvent is evaporated. This can be accomplished at room temperature or, in the case of suitable driers, at higher temperatures, preferably of 40 to 60° C. in the roll-to-roll process at speeds of >1 m/min.

The step sequence of the coating with polysilazane solution followed by evaporation of the solvent is optionally repeated once, twice or more than twice, in order to obtain a dry unhardened (“green”) polysilazane layer with a total thickness of 100 to 3000 nm. By repeated passage through the step sequence of coating and drying, the content of solvent in the green polysilazane layer is greatly reduced or eliminated. This measure allows the adhesion of the hardened polysilazane film on the chalcopyrite layer structure to be improved. A further advantage of repeated coating and drying is that any holes or cracks present in individual layers are substantially covered and closed, such that water vapor permeability is reduced further.

The dried or green polysilazane layer is converted to a transparent ceramic phase by hardening at a temperature in the range from 100 to 180° C. over a period of 0.5 to 1 h. The hardening is effected in a convection oven which is operated either with filtered and steam-moistened air or with nitrogen. According to the temperature, duration and oven atmosphere—steam-containing air or nitrogen—the ceramic phase has a different composition. When the hardening is effected, for example, in steam-containing air, a phase of the composition SiNᵥH_{w}OₓC_{y} where x>v; v<1; 0<x<1.3; 0≦w≦2.5 and y<0.5 is obtained. In the case of hardening in a nitrogen atmosphere, in contrast, a phase of the composition SiNᵥH_{w}OₓC_{y} where v<1.3; x<0.1; 0≦w≦2.5 and y<0.2 is formed.

The water vapor permeability can also be reduced by hardening the polysilazane layer once more. This “after-curing” is effected especially at a temperature around 85° C. in air with a relative humidity of 85% over a period of 1 h. Spectroscopic analyses show that the after-curing significantly reduces the nitrogen content of the polysilazane layer.

The features of the invention disclosed in the above description, in the claims and in the drawings, either individually or in any desired combination, may be essential for the implementation of the invention in its different embodiments.

1. A chalcopyrite solar cell comprising a substrate, a photovoltaic layer structure and an encapsulation layer based on polysilazane.

2. The solar cell (40) as claimed in claim 1, wherein the solar cell is configured as a thin-film solar cell and has a photovoltaic layer structure of the copper indium sulfide (CIS) or copper indium gallium selenide (CIGSe) type.

3. The solar cell as claimed in claim 1, wherein the photovoltaic layer structure comprises a rear contact (41) composed of molybdenum, an absorber of the composition CuInSe₂, CuInS₂, CuGaSe₂, CuIn₁₋ₓGaₓSe₂ where 0<x≦0.5 or Cu(InGa)(Se_{1-y}S_{y})₂ where 0<y≦1, a buffer composed of CdS, a window layer composed of ZnO or ZnO:Al, and a front contact composed of Al or silver.

4. The solar cell as claimed in claim 1, wherein the substrate includes a material comprising metal, metal alloys, glass, ceramic or plastic.

5. The solar cell as claimed in claim 1, wherein the substrate is in the form of a foil.

6. The solar cell as claimed in claim 1, wherein the encapsulation layer has a thickness of 100 to 3000 nm.

7. The solar cell as claimed in claim 1, wherein the substrate includes an electrically conductive material, and wherein the one or more of the layers of which the photovoltaic layer structure is composed have been deposited electrolytically.

8. The solar cell as claimed in claim 1, wherein the solar cell comprises a barrier layer based on a polysilazane arranged between the substrate and the photovoltaic layer structure.

9. The solar cell as claimed in claim 8, wherein the barrier layer contains sodium or comprises a sodium-containing precursor layer.

10. The solar cell as claimed in claim 1, wherein the encapsulation layer and optionally the barrier layer (2) includes a hardened solution of at least one polysilazane and additives in a solvent.

11. The solar cell (10) as claimed in claim 10, wherein the at least one polysilazane has the general structural formula (I)
—(SiR′R″—NR′″)n- (I)
where R′, R″, R′″ are the same or different and are each independently hydrogen or an optionally substituted alkyl, aryl, vinyl or (trialkoxysilyl)alkyl radical, where n is an integer and is such that the at least one polysilazane has a number-average molecular weight of 150 to 150 000 g/mol.

12. The solar cell as claimed in claim 11, wherein at least one polysilazane is selected from the group of the perhydropolysilazanes where R′, R″ and R′″═H.

13. The solar cell as claimed in claim 1, wherein the solar cell has a mean relative reflectivity for light in the wavelength range from 300 to 900 nm of less than 97% based on the reflectivity of the solar cell before application of he encapsulation layer.

14. The solar cell as claimed in claim 1, wherein the solar cell has a mean relative reflectivity for light in the wavelength range from 1100 to 1500 nm of more than 120% based on the reflectivity of the solar cell before application of the encapsulation layer.

15. The solar cell as claimed in claim 1, wherein the solar cell has an efficiency of greater than 70%, based on the starting value, in an accelerated aging test to DIN EN 61646 after 800 h.

16. A process for producing a chalcopyrite solar cell, comprising the steps of:
a) applying a photovoltaic layer structure based on chalcopyrite to a substrate optionally provided with a barrier layer,
b) coating the photovoltaic layer structure with a solution comprising at east one polysilazane of the general formula (I)
—(SiR′R″—NR′″)n- (I)
where R′, R″, R′″ are the same or different and are hydrogen or an optionally substituted alkyl, aryl, vinyl or (trialkoxysilyl)alkyl radical, where n is an integer and is such that the at least one polysilazane has a number-average molecular weight of 150 to 150 000 g/mol,
c) removing the solvent by evaporation to obtain a polysilazane layer having a thickness of 100 to 3000 nm,
d) optionally repeating steps b) and c) once or more than once,
e) hardening the polysilazane layer by i) heating to a temperature in the range from 20 to 1000° C., ii) irradiating with UV light having wavelength components in the range from 180 to 230 nm, or both, the heating, irradiation or both is effected over a period of 1 min to 14 h,
and
f) optionally further hardening the polysilazane layer at a temperature of 20 to 1000° C., in air having a relative humidity of 60 to 90% over a period of 1 min to 2 h.

17. The process as claimed in claim 16, wherein the polysilazane solution comprises at least one perhydropolysilazane where R′, R″ and R′″═H.

18. The process as claimed in claim 16, wherein the polysilazane solution comprises a catalyst, and optionally further additives.

19. The process as claimed in claim 16, wherein the chalcopyrite solar cell is manufactured on a flexible weblike substrate in a roll-to-roll process.

20. A chalcopyrite thin-film solar cell of the copper indium sulfide (CIS) or copper indium gallium selenide (CIGSe) type, wherein the solar cell has at least one encapsulation layer and wherein the at least one encapsulation layer is produced using a polysilazane solution comprising at least one polysilazane of the general formula (I)
—(SiR′R″—NR′″)n- (I)
where R′, R″, R′″ are the same or different and are each independently hydrogen or an optionally substituted alkyl, aryl, vinyl or (trialkoxysilyl)alkyl radical, where n is an integer and is such that the polysilazane has a number-average molecular weight of 150 to 150 000 g/mol.

21. The solar cell as claimed in claim 5, wherein the foil is in the form of a steel foil.

22. The solar cell as claimed in claim 5, wherein the foil is in the form of a titanium foil.

23. The solar cell as claimed in claim 1, wherein the encapsulation layer has a thickness of 200 to 2500 nm.

24. The solar cell as claimed in claim 1, wherein the encapsulation layer has a thickness of 300 to 2000 nm.

25. The solar cell as claimed in claim 1, wherein the solvent is dibutyl ether,

26. The solar cell as claimed in claim 11, wherein the at least one polysilazane has a number-average molecular weight of 50 000 to 150 000 g/mol.

27. The solar cell as claimed in claim 11, wherein the at least one polysilazane has a number-average molecular weight of 100 000 to 150 000 g/mol.

28. The solar cell as claimed in claim 1, wherein the solar cell has a mean relative reflectivity for light in the wavelength range from 300 to 900 nm of less than 96%, based on the reflectivity of the solar cell before application of the encapsulation layer.

29. The solar cell as claimed in claim 1, wherein the solar cell has a mean relative reflectivity for light in the wavelength range from 300 to 900 nm of less than 95%, based on the reflectivity of the solar cell before application of the encapsulation layer.

30. The solar cell as claimed in claim 1, wherein the solar cell has a mean relative reflectivity for light in the wavelength range from 1100 to 1500 nm of more than 150%, based on the reflectivity of the solar cell before application of the encapsulation layer.

31. The solar cell as claimed in claim 1, wherein the solar cell has a mean relative reflectivity for light in the wavelength range from 1100 to 1500 nm of more than 200%, based on the reflectivity of the solar cell before application of the encapsulation layer.

32. The solar cell as claimed in claim 1, wherein the solar cell has an efficiency of greater than 75%, based on the starting value, in an accelerated aging test to DIN EN 61646 after 800 h.

33. The solar cell as claimed in claim 1, wherein the solar cell has an efficiency of greater than 80%, based on the starting value, in an accelerated aging test to DIN EN 61646 after 800 h.

34. The process as claimed in claim 16, wherein the at least one polysilazane has a number-average molecular weight of 50 000 to 150 000 g/mol.

35. The process as claimed in claim 16, wherein the at least one polysilazane has a number-average molecular weight of 100 000 to 150 000 g/mol.

36. The process as claimed in claim 16, wherein the polysilazane layer has a thickness of 200 to 2500 nm.

37. The process as claimed in claim 16, wherein the polysilazane layer has a thickness of 300 to 2000 nm.

38. The process as claimed in claim 16, wherein the polysilazane layer is heated to a temperature in the range of 80 to 200° C.

39. The process as claimed in claim 16, wherein the heating, irradiation or both is effected over a period of 1 min to 60 min.

40. The process as claimed in claim 16, wherein the heating, irradiation or both is effected over a period of 1 min to 30 min.

41. The process as claimed in claim 16, wherein the heating, irradiation or both is in an atmosphere of water vapor-containing air or nitrogen.

42. The process as claimed in claim 16, wherein the further hardening of the polysilazane layer occurs at a temperature of 60 to 130° C.

43. The process as claimed in claim 16, wherein the further hardening of the polysilazane layer takes place over a period of 30 min to 1 h.
